(19) United States
(12) Patent Application Publication
(10) Pub. No.: US 2017/0261855 A1
(43) Pub. Date: Sep. 14, 2017

(54) METHODS FOR PREPARING ENCAPSULATED MARKINGS ON DIAMONDS

(71) Applicant: UAB Research Foundation, Birmingham, AL (US)

(72) Inventors: Samuel Moore, Birmingham, AL (US); Gopi Krishna Samudrala, Birmingham, AL (US)

(21) Appl. No.: 15/456,334

(22) Filed: Mar. 10, 2017

Related U.S. Application Data
(60) Provisional application No. 62/306,583, filed on Mar. 10, 2016.

(51) Int. Cl. G03F 7/16; C23C 16/02; G03F 7/20; C23F 1/00; C23C 14/34; C23C 14/18; C23C 16/27; H01J 37/32

(52) U.S. Cl. CPC G03F 7/167; C23C 16/27; C23C 16/0227; H01J 37/32192; C23F 1/00; C23C 14/34; C23C 14/185; G03F 7/70058; H01J 2237/334

(57) ABSTRACT

In one aspect, the invention relates to methods to prepare markings on diamond surfaces which are encapsulated by diamond, and the marked diamonds prepared by the disclosed methods. This abstract is intended as a scanning tool for purposes of searching in the particular art and is not intended to be limiting of the present invention.

### CROSS-REFERENCE TO RELATED APPLICATIONS

This Application claims the benefit of U.S. Provisional Application No. 62/306,583, filed on Mar. 10, 2016, which is incorporated herein by reference in its entirety.

### STATEMENT REGARDING FEDERALLY SPONSORED RESEARCH

This invention was made with government support under grant number IIP-1317210, awarded by the National Science Foundation Partnership for Innovation (NSF:PFI) program, and under grant number DE-NA0002014, awarded by the Department of Energy (DOE)-National Nuclear Security Administration. The government has certain rights in the invention.

### BACKGROUND

Historically, marking of a diamond was not considered practical because it is the hardest material on Earth. Currently available techniques for marking a diamond are restricted to laser and ion beam technologies. These technologies can produce markings on a diamond that can be reduced to such a small scale that it is invisible to the naked eye or under the observation of a loupe with a ten times magnification, and it does not affect the clarity or the color grade of the diamond. The markings can also be made so large that it is visible to the naked eye, and certain desired special visual effects can be produced by the aforementioned processes to enhance the appeal of a diamond. Such markings on a diamond can be, for instance, the logo of the company responsible for the cutting, polishing, and setting of the diamond. It can also be the miniaturized signature or even photograph of the jeweler or artist. In principle, the marks created by either laser or ion beam can be used as a form of identification.

Unfortunately, these techniques suffer from a number of shortcomings. For example, laser marking methods can burn or graphitize the surface of the diamond. Moreover, these methods can damage the lattice structure of the diamond or remove diamond material from the diamond. These methods also do not allow the marking to incorporate precious metals such as platinum, palladium, and gold, or refractory metals such as tungsten or molybdenum.

Despite the currently available technologies for marking a diamond, there remains a need for improved methods of creating marks on a diamond that do not damage the diamond surface by burning or graphitizing the surface and do not remove diamond material as a result of the marking process. Accordingly, there remains a need for methods of marking a diamond that overcomes the limitations of currently available methods, and further allows the incorporation of one or more precious metals into the mark.

### SUMMARY

In accordance with the purpose(s) of the invention, as embodied and broadly described herein, the invention, in one aspect, relates to methods to prepare markings on diamond surfaces that are encapsulated by diamond, and the marked diamonds prepared by the disclosed methods.

Disclosed are methods for preparing an encapsulated marked diamond, the method comprising: (a) providing a diamond substrate having a surface; (b) depositing a uniform metal layer onto the surface; (c) coating the surface with a positive tone photoresist or a negative tone photoresist; (d) exposing the surface to light, thereby making the positive tone photoresist soluble in developing solution or thereby making the negative tone photoresist insoluble in developing solution; (e) developing the coating after light exposure, thereby creating a pattern, thereby exposing any excess metal, and thereby exposing a portion of the surface; (f) dissolving the excess metal; (g) stripping the polymer resist coating; and (h) encapsulating the surface with single crystal diamond.

Also disclosed are methods for preparing an encapsulated marked diamond, the method comprising: (a) providing a diamond substrate having a surface; (b) applying a uniform polymer photoresist coating onto the surface; (c) exposing the substrate to light, thereby making the positive tone photoresist coating soluble in a developing solution or thereby making the negative tone photoresist insoluble in a developing solution; (d) developing the photoresist coating after light exposure, thereby creating a pattern, thereby exposing any excess metal, and thereby exposing a portion of the surface; (e) depositing a uniform metal layer onto the portion of the surface; (f) stripping the polymer resist coating; and (g) encapsulating the surface with single crystal diamond.

Also disclosed are methods comprising: (a) providing a diamond substrate having a surface; (b) applying a uniform polymer photoresist coating onto the surface; (c) exposing the substrate to light, wherein the light etches a pattern onto the polymer resist coating, thereby exposing a portion of the surface; (d) depositing a uniform metal layer onto the portion of the surface; (e) stripping the polymer resist coating; and (f) encapsulating the surface with single crystal diamond.

Also disclosed are inscription methods comprising: (1) performing photolithography on a surface of a diamond substrate, thereby producing an marking on the surface; and (2) forming a single crystal diamond on top of the marking, thereby encapsulating the marking.

Also disclosed are marked diamonds prepared by the disclosed methods.

While aspects of the present invention can be described and claimed in a particular statutory class, such as the system statutory class, this is for convenience only and one of skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

### BRIEF DESCRIPTION OF THE DRAWINGS

The accompanying figures, which are incorporated in and constitute a part of this specification, illustrate several aspects and together with the description serve to explain the principles of the invention.

FIG. 1A-C show schematic representations of the disclosed methods. Specifically, FIG. 1A shows in the top row the steps involved in fabricating a designer diamond through the wet etch process, and in the bottom row shows the steps involved in fabricating designer diamond anvils through the lift-off process. FIG. 1B shows an alternative schematic representation of the steps involved in fabricating designer diamond anvils through the wet etch process. FIG. 1C shows an alternative schematic representation of the steps involved in fabricating a designer diamond through the lift-off process.

FIG. 2 shows a representative diamond substrate that has been cleaned by the disclosed methods and is ready to be used in subsequent steps of the disclosed methods.

FIG. 3 shows a representative diamond plate that has been coated with tungsten metal by sputter deposition.

FIG. 4A and FIG. 4B show a representative gem diamond coated with tungsten metal, with each of FIG. 4A and FIG. 4B showing different views of the same diamond. Arrow marks indicate representative locations on which markings can be drawn, such as the culet and table of the diamond, according to the disclosed methods.

FIG. 5 shows representative markings prepared on a diamond using maskless lithography.

FIG. 6 shows representative encapsulated markings prepared on a diamond according to the disclosed methods. Specifically, FIG. 6 shows the marking in FIG. 5 after encapsulation.

Additional advantages of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

Still other objects and advantages of the present disclosure will become readily apparent by those skilled in the art from the following detailed description, wherein it is shown and described only the preferred embodiments, simply by way of illustration of the best mode. As will be realized, the disclosure is capable of other and different embodiments, and its several details are capable of modifications in various obvious respects, without departing from the disclosure. Accordingly, the description is to be regarded as illustrative in nature and not as restrictive.

### DETAILED DESCRIPTION

The present invention can be understood more readily by reference to the following detailed description of the invention and the examples included therein.

Before the present compounds, compositions, articles, systems, devices, and/or methods are disclosed and described, it is to be understood that they are not limited to specific synthetic methods unless otherwise specified, or to particular reagents unless otherwise specified, as such may, of course, vary. It is also to be understood that the terminology used herein is for the purpose of describing particular aspects only and is not intended to be limiting. Although any methods and materials similar or equivalent to those described herein can be used in the practice or testing of the present invention, example methods and materials are now described.

While aspects of the present invention can be described and claimed in a particular statutory class, such as the system statutory class, this is for convenience only and one of skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is in no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

Throughout this application, various publications are referenced. The disclosures of these publications in their entireties are hereby incorporated by reference into this application in order to more fully describe the state of the art to which this pertains. The references disclosed are also individually and specifically incorporated by reference herein for the material contained in them that is discussed in the sentence in which the reference is relied upon. Nothing herein is to be construed as an admission that the present invention is not entitled to antedate such publication by virtue of prior invention. Further, the dates of publication provided herein may be different from the actual publication dates, which can require independent confirmation.

### A. DEFINITIONS

As used herein, the terms “about,” “approximate,” and “at or about” mean that the amount or value in question can be the exact value designated or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

### B. ENCAPSULATED MARKED DIAMONDS

In one aspect, disclosed are encapsulated marked diamonds prepared by a disclosed method. In a further aspect, the method comprises: (a) providing a diamond substrate having a surface; (b) depositing a uniform metal layer onto the surface; (c) coating the surface with a positive tone photoresist or a negative tone photoresist; (d) exposing the surface to light, thereby making the positive tone photoresist soluble in developing solution or thereby making the negative tone photoresist insoluble in developing solution; (e) developing the coating after light exposure, thereby creating a pattern, thereby exposing any excess metal, and thereby exposing a portion of the surface; (f) dissolving the excess metal; (g) stripping the polymer resist coating; and (h) encapsulating the surface with single crystal diamond.

In a still further aspect, the method comprises: (a) providing a diamond substrate having a surface; (b) applying a uniform polymer photoresist coating onto the surface; (c) exposing the substrate to light, wherein the light etches a pattern onto the polymer resist coating, thereby exposing a portion of the surface; (d) depositing a uniform metal layer onto the portion of the surface; (e) stripping the polymer resist coating; and (f) encapsulating the surface with single crystal diamond.

Without wishing to be bound by theory, encapsulated marked diamonds can serve a host of purposes, most notably, securing the diamond and personalizing the diamond. For example, a diamond can be marked with a certification number from the laboratory where it was certified. In this way, the number can be used to identify the diamond if it is in need of service of if it is lost or stolen. This can significantly increase the likelihood of recovery. Alternatively, a diamond can be marked with a personalized message such as, for example, a proposal date, an inside joke, or some other reference personal to a couple.

### C. METHODS OF PREPARING ENCAPSULATED DIAMONDS

In one aspect, disclosed are methods for preparing an encapsulated marked diamond, the method comprising: providing a diamond substrate having a surface; depositing a uniform metal layer onto the surface; coating the surface with a positive tone photoresist or a negative tone photoresist; exposing the surface to light, thereby making the positive tone photoresist soluble in developing solution or thereby making the negative tone photoresist insoluble in developing solution; developing the coating after exposing it to light, thereby creating a pattern onto the coating, thereby exposing any excess metal, and thereby exposing a portion of the surface; dissolving the excess metal; stripping the polymer resist coating; and encapsulating the surface with single crystal diamond.

In a further aspect, disclosed are methods for preparing an encapsulated marked diamond, the method comprising: providing a diamond substrate having a surface; applying a uniform polymer photoresist coating onto the surface; exposing the substrate to light, wherein the light etches a pattern onto the polymer resist coating, thereby exposing a portion of the surface; depositing a uniform metal layer onto the portion of the surface; stripping the polymer resist coating; and encapsulating the surface with single crystal diamond.

In one aspect, disclosed are inscription methods comprising: (1) performing photolithography on a surface of a diamond substrate, thereby producing an marking on the surface; and (2) forming a single crystal diamond on top of the marking, thereby encapsulating the marking.

Thus, in various aspects, the disclosed methods provide for preparation of high resolution, highly customizable markings on diamonds such as, logos, labels, captions, and numbers. The markings can be printed onto a diamond surface and encapsulated in a single crystal of diamond using sputter deposition, maskless lithographic techniques and chemical vapor deposition (CVD). The marking produced by the disclosed methods becomes an inherent part of the single crystal of diamond, rendering it extremely difficult to remove—requiring advanced polishing equipment and technical knowledge to effect such removal.

In various aspects, the process of rendering a custom inscription on the diamond surface prior to its encapsulation consists of using sputter deposition and maskless photolithography techniques. For mass produced identically patterned substrates, masked lithographic techniques could be used to more efficiently process and output the diamonds. The inscription can be patterned onto the surface successfully in one of two ways: a wet etch process or a lift-off process.

In a further aspect, the wet etch process comprises initially sputter coating a diamond surface with a metal so that the entire surface is covered with a metallic layer, typically 0.1-1 micron thick. Next, a coating of photo-sensitive material (known as photoresist) is deposited uniformly over the metal layer. The photoresist is then patterned with a custom design (that will become the inscription) using the maskless photolithographic instrument. The resist material is typically exposed with light in the 360-450 nm range in a very precise and high resolution pattern (on the order of a few microns) via the digital micromirror device contained on the lithographic instrument. Both positive tone resists (material that is exposed becomes soluble during development) and negative tone resists (material that is exposed becomes insoluble during development) can be used if the artwork used for lithographic processing is altered accordingly. The unwanted excess resist on the metal layer is then dissolved using an aqueous developer solution. Only the resist on top of the metal that will ultimately display the intended inscription will now remain. This resist acts as a masking or protective layer during the wet etch process in which all metal that is not masked by the resist will be removed in a bath of metallic etchant. After the metallic etch process is complete, the remaining resist is removed from the metallic pattern and the inscribed diamond is ready for the encapsulation phase through chemical vapor deposition.

In a further aspect, the lift-off process is essentially the reverse process of the wet etch procedure previously described. In a lift-off process the lithographic patterning process is performed on the diamond prior to sputter deposition. The diamond is first coated in a single (or bi-layer) coating of photoresist before the metal deposition phase. In this method the resist remains in regions where metal is not wanted on the final diamond surface. This allows for the resist to mask or protect the diamond surface from any metal deposits when the next step of sputter deposition occurs. In regions where photoresist is absent, metal will be deposited directly onto the diamond surface. This metal will become the final pattern on the diamond. After sputter deposition the excess resist is then removed by using a photoresist solvent and only the final metal pattern remains. At this stage the diamond is ready for the chemical vapor deposition encapsulation phase.

Once the message rendering phase (sputter coating and maskless lithography) is finished, the encapsulation phase begins. This is achieved by essentially “adding” more diamond to the existing diamond substrate through chemical vapor deposition. Through the implementation of various chemistries and growth parameters during CVD, the maskless lithographic pattern that is imprinted on the diamond surface will be encapsulated in diamond, as the single crystal grows as a continuation of the underlying or pre-existing diamond. Both lab grown and mined diamonds can be utilized for this technique. Again, through altering the CVD growth parameters the lithographic message can be imprinted on any crystallographic plane of the diamond. This makes the imprinting technique very versatile.

The final step which may or may not be necessary is polishing the final diamond surface. If CVD chemistries are utilized that focus on growth and surface quality (but usually have slower growth rates) then required polishing may be minimal, or may not be necessary at all. If CVD chemistries are utilized that promote rapid growth and slightly poorer surface quality, then polishing will be required.

The disclosed methods provide several advantages over currently available processes for marking a diamond surface: (a) the disclosed methods increase the overall size of the diamonds rather than remove material from the diamond; (b) the disclosed methods do not graphitize the surface of the diamonds; (c) the disclosed methods provide for a marking comprising a precious metal; (d) the disclosed methods provide a marked surface that is easier to keep clean, as debris will not be able to fill in/or attach to inscription; and (e) the disclosed methods provide for a marking that is encased in a single crystal of diamond, therefore it will be much more difficult to remove and thus more valuable if intended for security purposes.

In various aspects, the present invention relates to methods for preparing an encapsulated marked diamond, the method comprising: (a) providing a diamond substrate having a surface; (b) depositing a uniform metal layer onto the surface; (c) applying a uniform polymer photoresist coating onto the metal layer; (d) exposing the substrate to light, makes positive tone photoresist coating soluble in a developing solution, makes negative tone photoresist insoluble in a developing solution; (e) the process of developing the photoresist coating after exposing it to light, which creates a pattern onto the photoresist coating, thereby exposing any excess metal; (f) dissolving the excess metal; (g) stripping the polymer resist coating; and (h) encapsulating the surface with single crystal diamond thereby preparing an encapsulated marked diamond.

In a further aspect, the substrate is a single crystal. The single crystal can be of any size such as, for example, greater than one carat, one carat, or less than one carat. In yet a further aspect, the single crystal is about one-third carat.

In a further aspect, depositing a uniform metal layer comprises sputter deposition.

In a further aspect, the metal layer comprises tungsten, gold, platinum, or palladium, or combinations thereof. In a still further aspect the metal comprises tungsten. In a yet further aspect the metal comprises platinum. In an even further aspect the metal comprises gold. In a still further aspect the metal comprises palladium.

In a further aspect, the metal layer comprises a refractory metal. Examples of refractory metals include, but are not limited to, tungsten and molybdenum.

In a further aspect, the metal layer is of from about 0.1 microns to about 2 microns. In a still further aspect, the metal layer is of from about 0.2 microns to about 2 microns. In a yet further aspect, the metal layer is of from about 0.3 microns to about 2 microns. In an even further aspect, the metal layer is of from about 0.4 microns to about 2 microns. In a still further aspect, the metal layer is of from about 0.5 microns to about 2 microns. In a yet further aspect, the metal layer is of from about 0.6 microns to about 2 microns. In an even further aspect, the metal layer is of from about 0.7 microns to about 2 microns. In a still further aspect, the metal layer is of from about 0.8 microns to about 2 microns. In a yet further aspect, the metal layer is of from about 0.9 microns to about 2 microns. In an even further aspect, the metal layer is of from about 1 micron to about 2 microns.

In a further aspect, the metal layer is of from about 0.1 microns to about 1 micron. In a yet further aspect, the metal layer is of from about 0.1 microns to about 0.9 microns. In an even further aspect, the metal layer is of from about 0.1 microns to about 0.8 microns. In a still further aspect, the metal layer is of from about 0.1 microns to about 0.7 microns. In a yet further aspect, the metal layer is of from about 0.1 microns to about 0.6 microns. In an even further aspect, the metal layer is of from about 0.1 microns to about 0.5 microns. In a still further aspect, the metal layer is of from about 0.1 microns to about 0.4 microns. In a still further aspect, the metal layer is of from about 0.1 microns to about 0.45 microns. In a yet further aspect, the metal layer is of from about 0.1 microns to about 0.4 microns.

In a further aspect, the metal layer is of from about 0.15 microns to about 1 micron. In a yet further aspect, the metal layer is of from about 0.15 microns to about 0.9 microns. In an even further aspect, the metal layer is of from about 0.15 microns to about 0.8 microns. In a still further aspect, the metal layer is of from about 0.15 microns to about 0.7 microns. In a yet further aspect, the metal layer is of from about 0.15 microns to about 0.6 microns. In an even further aspect, the metal layer is of from about 0.15 microns to about 0.5 microns. In a still further aspect, the metal layer is of from about 0.15 microns to about 0.45 microns. In a yet further aspect, the metal layer is of from about 0.15 microns to about 0.4 microns.

In a further aspect, the metal layer is of from about 0.2 microns to about 1 micron. In a yet further aspect, the metal layer is of from about 0.2 microns to about 0.9 microns. In an even further aspect, the metal layer is of from about 0.2 microns to about 0.8 microns. In a still further aspect, the metal layer is of from about 0.2 microns to about 0.7 microns. In a yet further aspect, the metal layer is of from about 0.2 microns to about 0.6 microns. In an even further aspect, the metal layer is of from about 0.2 microns to about 0.5 microns. In a still further aspect, the metal layer is of from about 0.2 microns to about 0.45 microns. In a yet further aspect, the metal layer is of from about 0.2 microns to about 0.4 microns.

In a further aspect, the metal layer is of from about 0.25 microns to about 1 micron. In a yet further aspect, the metal layer is of from about 0.25 microns to about 0.9 microns. In an even further aspect, the metal layer is of from about 0.25 microns to about 0.8 microns. In a still further aspect, the metal layer is of from about 0.25 microns to about 0.7 microns. In a yet further aspect, the metal layer is of from about 0.25 microns to about 0.6 microns. In an even further aspect, the metal layer is of from about 0.25 microns to about 0.5 microns. In a still further aspect, the metal layer is of from about 0.25 microns to about 0.45 microns. In a yet further aspect, the metal layer is of from about 0.25 microns to about 0.4 microns.

In a further aspect, applying is via a spin coater. Thus, in various aspects, applying a uniform polymer photoresist coating onto the surface is via a spin coater.

In a further aspect, the spin coater has an angular velocity of from about 1000 rpm to about 12000 rpm. In a yet further aspect, the spin coater has an angular velocity of from about 1000 rpm to about 11000 rpm. In an even further aspect, the spin coater has an angular velocity of from about 1000 rpm to about 10000 rpm. In a still further aspect, the spin coater has an angular velocity of from about 1000 rpm to about 9000 rpm. In a yet further aspect, the spin coater has an angular velocity of from about 1000 rpm to about 8000 rpm. In a still further aspect, the spin coater has an angular velocity of from about 1000 rpm to about 7000 rpm. In a still further aspect, the spin coater has an angular velocity of from about 1000 rpm to about 6000 rpm. In a still further aspect, the spin coater has an angular velocity of from about 1000 rpm to about 5000 rpm. In a still further aspect, the spin coater has an angular velocity of from about 1000 rpm to about 4000 rpm. In a still further aspect, the spin coater has an angular velocity of from about 1000 rpm to about 3000 rpm. In a still further aspect, the spin coater has an angular velocity of from about 1000 rpm to about 2000 rpm.

In a further aspect, the spin coater has an angular velocity of from about 2000 rpm to about 12000 rpm. In a yet further aspect, the spin coater has an angular velocity of from about 3000 rpm to about 12000 rpm. In an even further aspect, the spin coater has an angular velocity of from about 4000 rpm to about 12000 rpm. In a still further aspect, the spin coater has an angular velocity of from about 5000 rpm to about 12000 rpm. In a yet further aspect, the spin coater has an angular velocity of from about 6000 rpm to about 12000 rpm. In a still further aspect, the spin coater has an angular velocity of from about 7000 rpm to about 12000 rpm. In a still further aspect, the spin coater has an angular velocity of from about 8000 rpm to about 12000 rpm. In a still further aspect, the spin coater has an angular velocity of from about 9000 rpm to about 12000 rpm. In a still further aspect, the spin coater has an angular velocity of from about 9000 rpm to about 12000 rpm. In a still further aspect, the spin coater has an angular velocity of from about 10000 rpm to about 12000 rpm. In a still further aspect, the spin coater has an angular velocity of from about 11000 rpm to about 12000 rpm.

In a further aspect, the spin coater has an angular velocity of about 1000 rpm, about 1500 rpm, about 2000 rpm, about 2500 rpm, about 3000 rpm, about 3500 rpm, about 4000 rpm, about 4500 rpm, about 5000 rpm, about 5500 rpm, about 6000 rpm, about 6500 rpm, about 7000 rpm, about 7500 rpm, about 8000 rpm, about 8500 rpm, about 9000 rpm, about 9500 rpm, about 10000 rpm, about 10500 rpm, about 11000 rpm, about 11500 rpm, or about 12000 rpm.

In a further aspect, the polymer photoresist coating comprises 1-methoxy-2-propanol acetate, gamma butyrolactone, or combinations thereof. In a still further aspect, the polymer photoresist coating is a positive tone resist. In a yet further aspect, the polymer photoresist coating is a negative tone resist. Commercially available positive tone resists useful in the disclosed methods include, but are not limited to, materials such as AZ 1500 series photoresists and Shipley 1800 series photoresists. Commercially available negative tone resists useful in the disclosed methods include, but are not limited to, materials such as AZ nLof series photoresists and Microchem's SU-8 series photoresists. Commercially available materials for the lift-off process useful in the disclosed methods include, but are not limited to, materials Microchem's PMGI/LOR.

In a further aspect, exposing the photoresist is via maskless lithography. In a still further aspect, photoresist exposing is via a digital micro mirror device. In a yet further aspect, the wavelength of the light is in the range of from about 360 nm to about 450 nm. In an even further aspect, the wavelength of the light is in the range of from about 436 nm. In a still further aspect, the wavelength of the light is in the range of from about 365 nm. These wavelengths can be generated by lasers and polychromatic light sources such as light emitting diodes, mercury arc lamps.

In a further aspect, dissolving the excess metal comprises wet etching. In a still further aspect, wet etching comprises exposing the surface to an acidic etchant solution. In a yet further aspect, stripping comprises exposing the surface to a solvent.

In a further aspect, encapsulating is via microwave plasma chemical vapor deposition. In a yet further aspect, encapsulating comprises the steps of: (a) providing a mixture comprising hydrogen and a carbon precursor; (b) establishing a plasma comprising the mixture; and (c) depositing carbon-containing species from the plasma onto the surface, thereby encapsulating the surface with single crystal diamond. In an even further aspect, the carbon precursor is a C1-C4 alkane. In a still further aspect, the C1-C4 alkane is methane.

In a further aspect, the ratio of the carbon precursor to hydrogen is in the range of about 1% to about 10%. In a still further aspect, the ratio of the carbon precursor to hydrogen is in the range of about 1% to about 9%. In a yet further aspect, the ratio of the carbon precursor to hydrogen is in the range of about 1% to about 8%. In an even further aspect, the ratio of the carbon precursor to hydrogen is in the range of about 1% to about 7%. In a still further aspect, the ratio of the carbon precursor to hydrogen is in the range of about 1% to about 6%. In a yet further aspect, the ratio of the carbon precursor to hydrogen is in the range of about 1% to about 5%. In an even further aspect, the ratio of the carbon precursor to hydrogen is in the range of about 1% to about 4%. In a still further aspect, the ratio of the carbon precursor to hydrogen is in the range of about 1% to about 3%. In a yet further aspect, the ratio of the carbon precursor to hydrogen is in the range of about 1% to about 2%.

In a further aspect, the ratio of the carbon precursor to hydrogen is in the range of about 2% to about 10%. In a still further aspect, the ratio of the carbon precursor to hydrogen is in the range of about 3% to about 10%. In a yet further aspect, the ratio of the carbon precursor to hydrogen is in the range of about 4% to about 10%. In an even further aspect, the ratio of the carbon precursor to hydrogen is in the range of about 5% to about 10%. In a still further aspect, the ratio of the carbon precursor to hydrogen is in the range of about 6% to about 10%. In a yet further aspect, the ratio of the carbon precursor to hydrogen is in the range of about 7% to about 10%. In an even further aspect, the ratio of the carbon precursor to hydrogen is in the range of about 8% to about 10%. In a still further aspect, the ratio of the carbon precursor to hydrogen is in the range of about 9% to about 10%.

In a further aspect, the ratio of the carbon precursor to hydrogen is in the range of about 1%, about 2%, about 3%, about 4%, about 5%, about 6%, about 7%, about 8%, about 9%, or about 10%.

In a further aspect, encapsulating comprises heating the surface. In a yet further aspect, encapsulating comprises heating the surface at a temperature of from about 800° C. to about 1300° C. In an even further aspect, encapsulating comprises heating the surface at a temperature of from about 900° C. to about 1300° C. In a still further aspect, encapsulating comprises heating the surface at a temperature of from about 1000° C. to about 1300° C. In a yet further aspect, encapsulating comprises heating the surface at a temperature of from about 1100° C. to about 1300° C. In an even further aspect, encapsulating comprises heating the surface at a temperature of from about 1200° C. to about 1300° C.

In a further aspect, encapsulating comprises heating the surface at a temperature of from about 800° C. to about 1200° C. In a still further aspect, encapsulating comprises heating the surface at a temperature of from about 800° C. to about 1100° C. In a yet further aspect, encapsulating comprises heating the surface at a temperature of from about 800° C. to about 1000° C. In an even further aspect, encapsulating comprises heating the surface at a temperature of from about 800° C. to about 900° C.

In a further aspect, encapsulating comprises heating the surface at a temperature of about 800° C., about 850° C., about 900° C., about 950° C., about 1000° C., about 1050° C., about 1100° C., about 1150° C., about 1200° C., about 1250° C., or about 1300° C.

In various aspects, the present invention relates to methods for preparing an encapsulated marked diamond, the method comprising: (a) providing a diamond substrate having a surface; (b) applying a uniform polymer photoresist coating onto the surface; (c) exposing the substrate to light, makes positive tone photoresist coating soluble in a developing solution, makes negative tone photoresist insoluble in a developing solution; (d) the process of developing the photoresist coating after exposing it to light, which creates a pattern onto the photoresist coating, thereby exposing any excess metal, thereby exposing a portion of the surface; (e) depositing a uniform metal layer onto the portion of the surface; (f) stripping the polymer resist coating; and (g) encapsulating the surface with single crystal diamond; thereby preparing an encapsulated marked diamond.

In a further aspect, the substrate is a single crystal. In a still further aspect, the single crystal is about one-third carat.

In a further aspect, applying is via a spin coater. Thus, in various aspects, applying a uniform polymer photoresist coating onto the surface is via a spin coater.

In a further aspect, the spin coater has an angular velocity of from about 1000 rpm to about 12000 rpm. In a yet further aspect, the spin coater has an angular velocity of from about 1000 rpm to about 11000 rpm. In an even further aspect, the spin coater has an angular velocity of from about 1000 rpm to about 10000 rpm. In a still further aspect, the spin coater has an angular velocity of from about 1000 rpm to about 9000 rpm. In a yet further aspect, the spin coater has an angular velocity of from about 1000 rpm to about 8000 rpm. In a still further aspect, the spin coater has an angular velocity of from about 1000 rpm to about 7000 rpm. In a still further aspect, the spin coater has an angular velocity of from about 1000 rpm to about 6000 rpm. In a still further aspect, the spin coater has an angular velocity of from about 1000 rpm to about 5000 rpm. In a still further aspect, the spin coater has an angular velocity of from about 1000 rpm to about 4000 rpm. In a still further aspect, the spin coater has an angular velocity of from about 1000 rpm to about 3000 rpm. In a still further aspect, the spin coater has an angular velocity of from about 1000 rpm to about 2000 rpm.

In a further aspect, the spin coater has an angular velocity of from about 2000 rpm to about 12000 rpm. In a yet further aspect, the spin coater has an angular velocity of from about 3000 rpm to about 12000 rpm. In an even further aspect, the spin coater has an angular velocity of from about 4000 rpm to about 12000 rpm. In a still further aspect, the spin coater has an angular velocity of from about 5000 rpm to about 12000 rpm. In a yet further aspect, the spin coater has an angular velocity of from about 6000 rpm to about 12000 rpm. In a still further aspect, the spin coater has an angular velocity of from about 7000 rpm to about 12000 rpm. In a still further aspect, the spin coater has an angular velocity of from about 8000 rpm to about 12000 rpm. In a still further aspect, the spin coater has an angular velocity of from about 9000 rpm to about 12000 rpm. In a still further aspect, the spin coater has an angular velocity of from about 9000 rpm to about 12000 rpm. In a still further aspect, the spin coater has an angular velocity of from about 10000 rpm to about 12000 rpm. In a still further aspect, the spin coater has an angular velocity of from about 11000 rpm to about 12000 rpm.

In a further aspect, the spin coater has an angular velocity of about 1000 rpm, about 1500 rpm, about 2000 rpm, about 2500 rpm, about 3000 rpm, about 3500 rpm, about 4000 rpm, about 4500 rpm, about 5000 rpm, about 5500 rpm, about 6000 rpm, about 6500 rpm, about 7000 rpm, about 7500 rpm, about 8000 rpm, about 8500 rpm, about 9000 rpm, about 9500 rpm, about 10000 rpm, about 10500 rpm, about 11000 rpm, about 11500 rpm, or about 12000 rpm.

In a further aspect, the polymer photoresist coating comprises 1-methoxy-2-propanol acetate, gamma butyrolactone, or combinations thereof. In a still further aspect, the polymer photoresist coating is a positive tone resist. In a yet further aspect, the polymer photoresist coating is a negative tone resist. Commercially available positive tone resists useful in the disclosed methods include, but are not limited to, materials such as AZ 1500 series photoresists and Shipley 1800 series photoresists. Commercially available negative tone resists useful in the disclosed methods include, but are not limited to, materials such as AZ nLof series photoresists and Microchem's SU-8 series photoresists.

In a further aspect, exposing the photoresist is via maskless lithography. In a still further aspect, photoresist exposing is via a digital micro mirror device. In a yet further aspect, the wavelength of the light is in the range of from about 360 nm to about 450 nm. In an even further aspect, the wavelength of the light is in the range of from about 436 nm. In a still further aspect, the wavelength of the light is in the range of from about 365 nm. These wavelengths can be generated by lasers and polychromatic light sources such as light emitting diodes, mercury arc lamps.

In a further aspect, depositing is via sputter deposition.

In a further aspect, the metal layer comprises tungsten, gold, platinum, or palladium, or combinations thereof. In a still further aspect the metal comprises tungsten. In a yet further aspect the metal comprises platinum. In an even further aspect the metal comprises gold. In a still further aspect the metal comprises palladium.

In a further aspect, the metal layer comprises a refractory metal. Examples of refractory metals include, but are not limited to, tungsten and molybdenum.

In a further aspect, the metal layer is of from about 0.1 microns to about 2 microns. In a still further aspect, the metal layer is of from about 0.2 microns to about 2 microns. In a yet further aspect, the metal layer is of from about 0.3 microns to about 2 microns. In an even further aspect, the metal layer is of from about 0.4 microns to about 2 microns. In a still further aspect, the metal layer is of from about 0.5 microns to about 2 microns. In a yet further aspect, the metal layer is of from about 0.6 microns to about 2 microns. In an even further aspect, the metal layer is of from about 0.7 microns to about 2 microns. In a still further aspect, the metal layer is of from about 0.8 microns to about 2 microns. In a yet further aspect, the metal layer is of from about 0.9 microns to about 2 microns. In an even further aspect, the metal layer is of from about 1 micron to about 2 microns.

In a further aspect, the metal layer is of from about 0.1 microns to about 1 micron. In a yet further aspect, the metal layer is of from about 0.1 microns to about 0.9 microns. In an even further aspect, the metal layer is of from about 0.1 microns to about 0.8 microns. In a still further aspect, the metal layer is of from about 0.1 microns to about 0.7 microns. In a yet further aspect, the metal layer is of from about 0.1 microns to about 0.6 microns. In an even further aspect, the metal layer is of from about 0.1 microns to about 0.5 microns. In a still further aspect, the metal layer is of from about 0.1 microns to about 0.4 microns. In a still further aspect, the metal layer is of from about 0.1 microns to about 0.45 microns. In a yet further aspect, the metal layer is of from about 0.1 microns to about 0.4 microns.

In a further aspect, the metal layer is of from about 0.15 microns to about 1 micron. In a yet further aspect, the metal layer is of from about 0.15 microns to about 0.9 microns. In an even further aspect, the metal layer is of from about 0.15 microns to about 0.8 microns. In a still further aspect, the metal layer is of from about 0.15 microns to about 0.7 microns. In a yet further aspect, the metal layer is of from about 0.15 microns to about 0.6 microns. In an even further aspect, the metal layer is of from about 0.15 microns to about 0.5 microns. In a still further aspect, the metal layer is of from about 0.15 microns to about 0.45 microns. In a yet further aspect, the metal layer is of from about 0.15 microns to about 0.4 microns.

In a further aspect, the metal layer is of from about 0.2 microns to about 1 micron. In a yet further aspect, the metal layer is of from about 0.2 microns to about 0.9 microns. In an even further aspect, the metal layer is of from about 0.2 microns to about 0.8 microns. In a still further aspect, the metal layer is of from about 0.2 microns to about 0.7 microns. In a yet further aspect, the metal layer is of from about 0.2 microns to about 0.6 microns. In an even further aspect, the metal layer is of from about 0.2 microns to about 0.5 microns. In a still further aspect, the metal layer is of from about 0.2 microns to about 0.45 microns. In a yet further aspect, the metal layer is of from about 0.2 microns to about 0.4 microns.

In a further aspect, the metal layer is of from about 0.25 microns to about 1 micron. In a yet further aspect, the metal layer is of from about 0.25 microns to about 0.9 microns. In an even further aspect, the metal layer is of from about 0.25 microns to about 0.8 microns. In a still further aspect, the metal layer is of from about 0.25 microns to about 0.7 microns. In a yet further aspect, the metal layer is of from about 0.25 microns to about 0.6 microns. In an even further aspect, the metal layer is of from about 0.25 microns to about 0.5 microns. In a still further aspect, the metal layer is of from about 0.25 microns to about 0.45 microns. In a yet further aspect, the metal layer is of from about 0.25 microns to about 0.4 microns.

In a further aspect, stripping comprises exposing the surface to a solvent.

In a further aspect, encapsulating is via microwave plasma chemical vapor deposition. In a yet further aspect, encapsulating comprises the steps of: (a) providing a mixture comprising hydrogen and a carbon precursor; (b) establishing a plasma comprising the mixture; and (c) depositing carbon-containing species from the plasma onto the surface, thereby encapsulating the surface with single crystal diamond. In an even further aspect, the carbon precursor is a C1-C4 alkane. In a still further aspect, the C1-C4 alkane is methane.

In a further aspect, the ratio of the carbon precursor to hydrogen is in the range of about 1% to about 10%. In a still further aspect, the ratio of the carbon precursor to hydrogen is in the range of about 1% to about 9%. In a yet further aspect, the ratio of the carbon precursor to hydrogen is in the range of about 1% to about 8%. In an even further aspect, the ratio of the carbon precursor to hydrogen is in the range of about 1% to about 7%. In a still further aspect, the ratio of the carbon precursor to hydrogen is in the range of about 1% to about 6%. In a yet further aspect, the ratio of the carbon precursor to hydrogen is in the range of about 1% to about 5%. In an even further aspect, the ratio of the carbon precursor to hydrogen is in the range of about 1% to about 4%. In a still further aspect, the ratio of the carbon precursor to hydrogen is in the range of about 1% to about 3%. In a yet further aspect, the ratio of the carbon precursor to hydrogen is in the range of about 1% to about 2%.

In a further aspect, the ratio of the carbon precursor to hydrogen is in the range of about 2% to about 10%. In a still further aspect, the ratio of the carbon precursor to hydrogen is in the range of about 3% to about 10%. In a yet further aspect, the ratio of the carbon precursor to hydrogen is in the range of about 4% to about 10%. In an even further aspect, the ratio of the carbon precursor to hydrogen is in the range of about 5% to about 10%. In a still further aspect, the ratio of the carbon precursor to hydrogen is in the range of about 6% to about 10%. In a yet further aspect, the ratio of the carbon precursor to hydrogen is in the range of about 7% to about 10%. In an even further aspect, the ratio of the carbon precursor to hydrogen is in the range of about 8% to about 10%. In a still further aspect, the ratio of the carbon precursor to hydrogen is in the range of about 9% to about 10%.

In a further aspect, the ratio of the carbon precursor to hydrogen is in the range of about 1%, about 2%, about 3%, about 4%, about 5%, about 6%, about 7%, about 8%, about 9%, or about 10%.

In a further aspect, encapsulating comprises heating the surface. In a yet further aspect, encapsulating comprises heating the surface at a temperature of from about 800° C. to about 1300° C. In an even further aspect, encapsulating comprises heating the surface at a temperature of from about 900° C. to about 1300° C. In a still further aspect, encapsulating comprises heating the surface at a temperature of from about 1000° C. to about 1300° C. In a yet further aspect, encapsulating comprises heating the surface at a temperature of from about 1100° C. to about 1300° C. In an even further aspect, encapsulating comprises heating the surface at a temperature of from about 1200° C. to about 1300° C.

In a further aspect, encapsulating comprises heating the surface at a temperature of from about 800° C. to about 1200° C. In a still further aspect, encapsulating comprises heating the surface at a temperature of from about 800° C. to about 1100° C. In a yet further aspect, encapsulating comprises heating the surface at a temperature of from about 800° C. to about 1000° C. In an even further aspect, encapsulating comprises heating the surface at a temperature of from about 800° C. to about 900° C.

### D. EXAMPLES

The following preparations and examples are given to enable those skilled in the art to more clearly understand and to practice the present disclosure. They should not be considered as limiting the scope of the disclosure, but merely as being illustrative and representative.

1. General Experimental Methods

Type-Ia and Type-IIa gem quality diamonds were utilized. High resolution and highly customizable patterns have been imprinted onto single crystal diamond (SCD) substrate anvil surfaces prior to being entirely encapsulated in SCD utilizing the following instrumentation: DC-sputter deposition, maskless lithography, and microwave plasma chemical vapor deposition (MPCVD). The DC-sputter deposition system is AJA International Inc.'s (Scituate, Mass., USA) Orion sputtering system with a sputter down configuration. The maskless lithography system is SF-100 Xcel system from Intelligent Micro Patterning LLC (St. Petersburg, Fla., USA). The maskless system allows patterns to be drawn on samples with extreme topography such as diamond anvils which have angles between surfaces ranging from 7° to 45°. The MPCVD system is a custom built system at the University of Alabama at Birmingham. The anvil geometries utilized consist of original culet sizes ranging from 10 to 600 microns, with bevel angles (angle between the culet and facet) ranging from 7° to 50°.

2. Lithographic Process (Method 1)

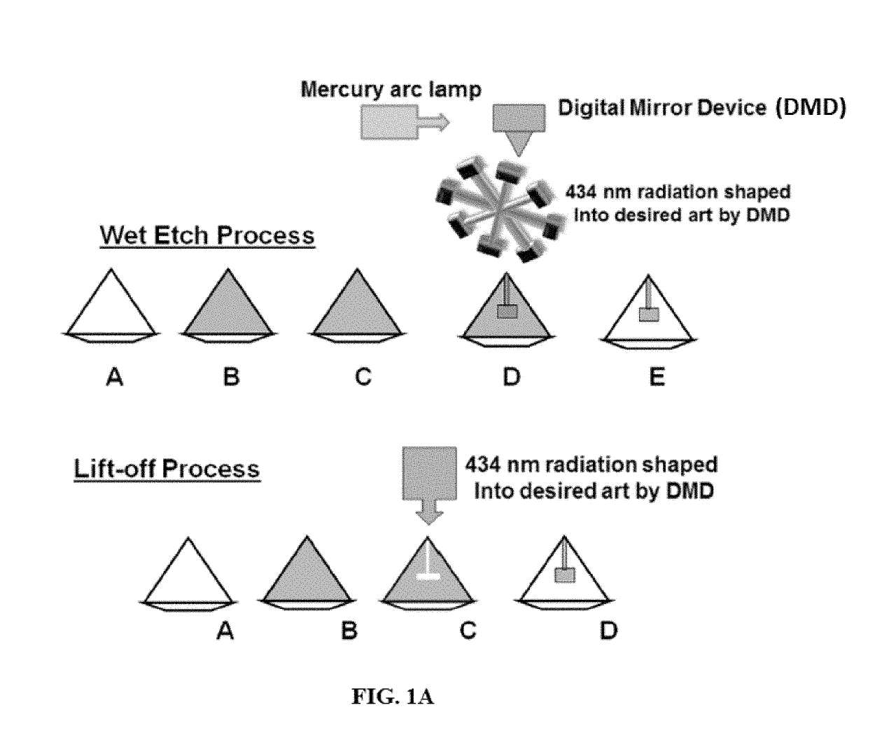

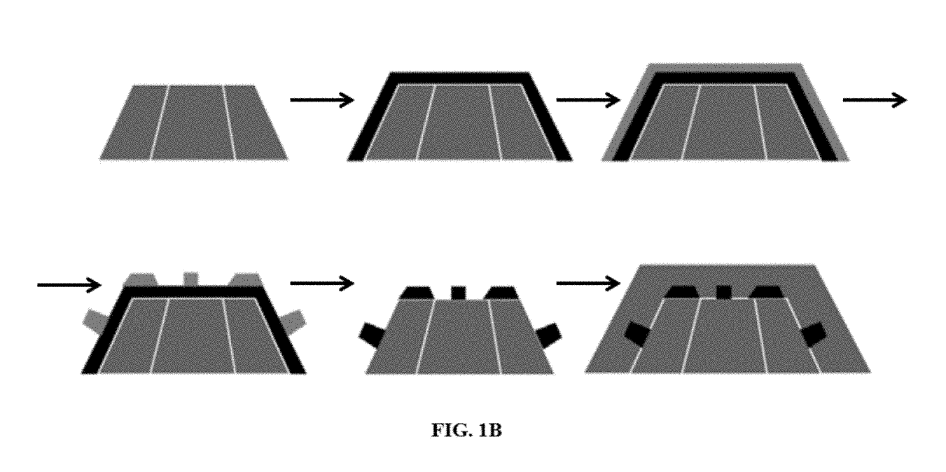

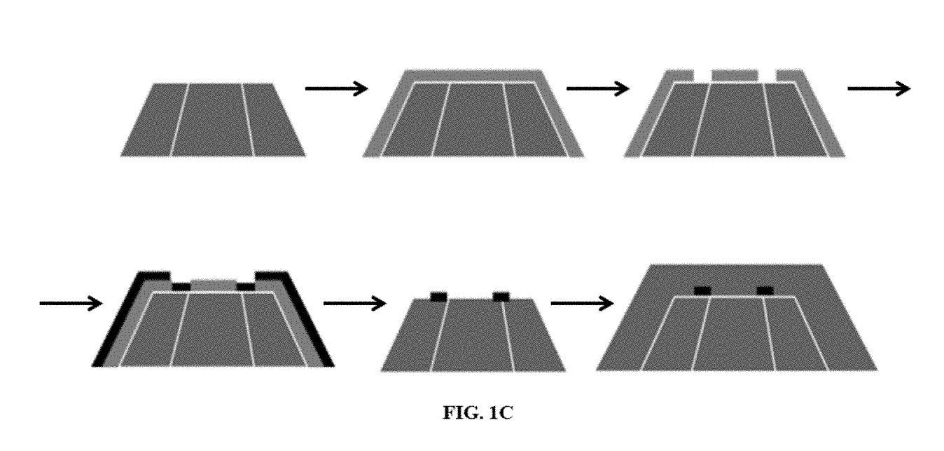

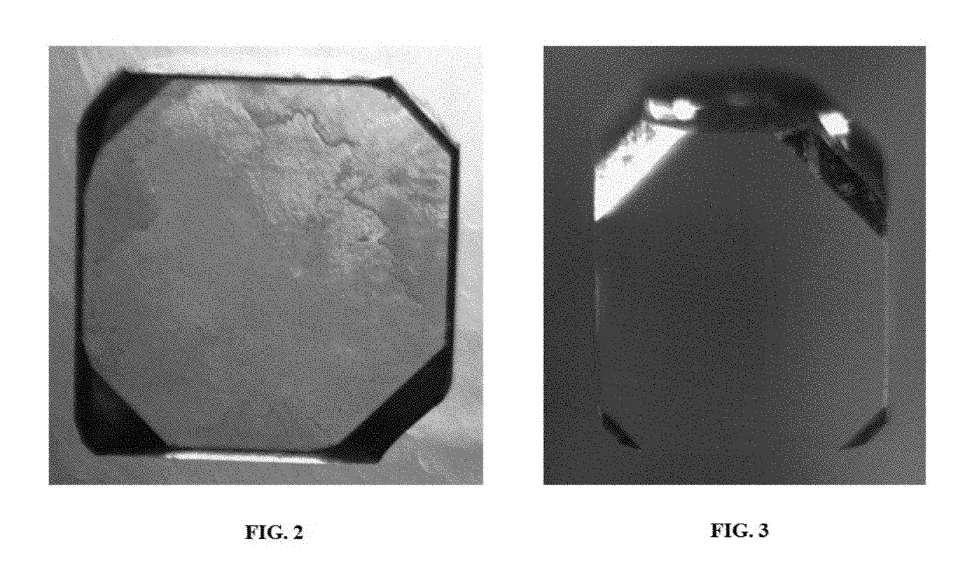

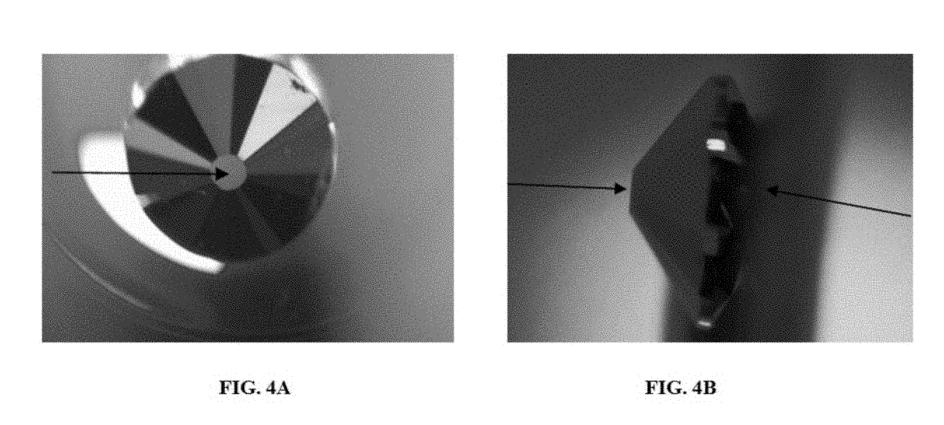

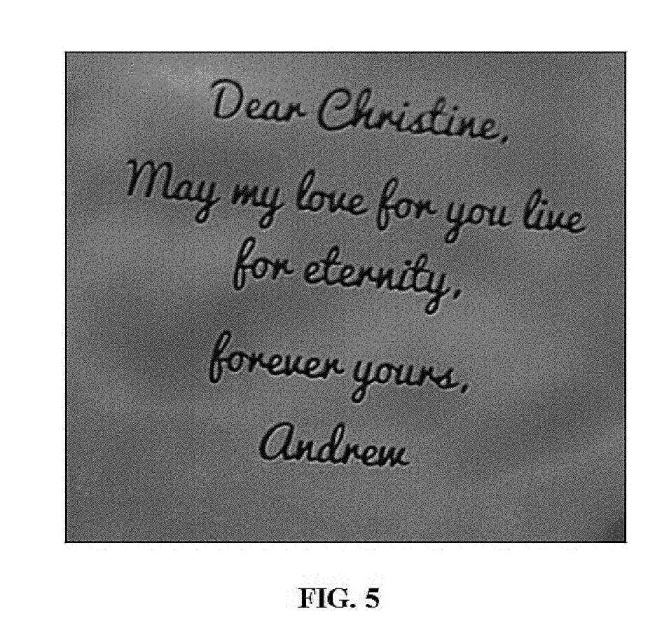

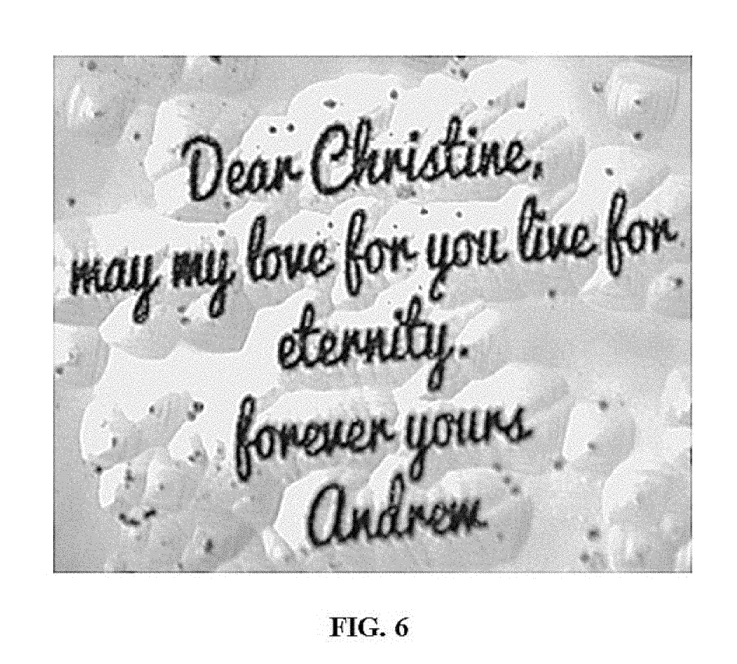

The top row (TR) of graphics in FIG. 1A outline the steps of obtaining encapsulated marks on diamond anvils with the use of positive (or negative) tone resist and wet etching. In this process, the bare diamond anvil substrate (TR-A) has been etched in a gentle RF-Plasma in the sputter deposition chamber prior to sputter coating. During the sputtering process, an RF bias has been maintained to ensure good quality metal film is deposited on the substrates. The substrate then has a uniform tungsten metal layer sputter deposited onto its surface so that the entire substrate is coated with a metallic layer (TR-B). The thickness of the metallic coating is in the range of 0.1-2 microns. After the metal has been sputter coated, photoresist (both positive tone and negative tone resists have been utilized to achieve the final result) is applied to the diamond using a spin coater with angular velocity ranging from 1000 to 12000 rotations per minute (rpm). The angular velocity is varied according to the anvil geometry in order to apply a uniform resist coating (TR-C). The resist has been processed according to manufacturer's recommendation by baking it at suitable temperature. The maskless photolithography instrument is then implemented to expose the substrate in very specific regions with visible light in the 360-450 nm range in a very high resolution pattern (micron scale resolution is achieved) via the digital micro mirror device (DMD) contained as an internal component of the maskless lithographic instrument (TR-D). Depending on the tone of the resist (positive resist becomes soluble when exposed to radiation, whereas negative resist becomes insoluble), the artwork loaded into the lithographic system software is designed specifically to meet the final circuit dimension specifications. The exposed resist is then placed in a developer solution and a pattern is rendered in the resist layer. The resist that remains is essentially a protective layer for the underlying tungsten film during the next phase of wet etching the substrate in a weakly acidic tungsten etchant. Once the etchant has completely dissolved the excess tungsten in the base layer, the substrate is removed from the solution and the photoresist layer is dissolved in a solvent. The result is a diamond anvil with a metallic pattern drawn on it (TR-E). The diamond anvil is then transferred into a 1.2 kW MPCVD chamber and SCD is grown at temperatures ranging from 800 to 1300° C. with a CH₄/H₂ ratio of 1%-10%. This results in the growth of CVD diamond with a thickness of 10-70 microns. The anvil is then polished until electrical contacts on the culet surface are exposed and the diagnostic contact pads on the facets are all exposed, facilitating the connection of external laboratory equipment.

3. Lithographic Process (Method 2)

The bottom row (BR) of FIG. 1A outlines the lift-off process. The lift-off process is essentially the reverse process of the wet etch procedure previously described. In the lift-off process the same instrumentation, materials, and process parameters outlined in the wet-etch method are used to perform the fabrication process. However, in this method resist coating and all lithographic process steps occur on the bare SCD substrate prior to sputter deposition (BR-A,B). As a result, once the lithographic process is completed the diamond surface regions in which metal will be deposited to render the final circuit pattern are exposed to incident tungsten atoms (BR-C). During sputter deposition tungsten particles coat these regions and adhere to the diamond substrate surface. After sputter deposition, the resist layer is stripped from the diamond anvil, and the excess tungsten deposited on top of the resist layer will be removed and only the final circuit pattern remains (BR-D). Resolution enhancement has been achieved by depositing an interstitial under layer of resist prior to applying an imaging resist layer. In this bi-layer method the interstitial layer (base layer of resist deposited directly onto the diamond) has a slightly higher dissolution rate than the imaging resist that is deposited on top of it, this results in an “overhang” effect during the development phase which leads to improved resolution as sputter deposited material is less likely to delaminate from the diamond surface due to attachment of tungsten to the resist coating during the resist stripping phase. Once sputter deposition and resist stripping is complete, the anvil undergoes the same steps as in the encapsulating MPCVD and polishing phase described in Method 1.

4. Generalized Method for the Fabrication of Encapsulated Marked Diamonds

The generalized method for the fabrication of encapsulated marked diamonds comprises utilizing maskless lithography and chemical vapor deposition. The steps involved in fabricating an encapsulated marked diamond are listed herein below. Briefly, the generalized method comprises the following steps: (1) cleaning the sample, e.g., boiling the diamond substrate in sulfuric acid in the temperature range of 80-120° C. or alternatively, a mixture of nitric acid and hydrochloric acid in 1:3 ratios; (2) drawing the desired pattern, on the diamond with a metal, wherein the drawing can be accomplished by either wet etching or a lift-off process; (3) when the desired pattern is drawn using a wet etching process, the steps comprise metal deposition, photoresist coating, exposing photoresist, photoresist developing, and chemical etching to remove the metal; (4) when the desired pattern is drawn using a lift-off process, the steps comprise photoresist coating, exposing photoresist, developing photoresist, metal deposition, and photoresist stripping; (5) once the desired pattern has been drawn on the diamond with a metal, the diamond is then placed in a chemical vapor deposition chamber to allow a layer of diamond to grow such that the diamond layer completely encapsulates the mark; and (6) the diamond is polished.

The process of obtaining encapsulated marks on diamond anvils with the use of positive (or negative) tone resist and wet etching are described further in the following generalized method, with reference to FIG. 1A:
(1) after the diamond is cleaned by way of boiling in acid, the bare diamond anvil substrate has been etched in a RF-Plasma in the sputter deposition chamber prior to sputter coating. An RF-power of 35 Watts can be used for this process which generates a bias of −300 volts on the sample. Depending on sample size, RF power in the range of 15-40 W can also be used.
(2) During the sputtering process, an RF bias (5 watts to 10 Watts) has been maintained to ensure that good quality metal film is deposited on the substrates.
(3) A typical sputter deposition run lasts 20-35 minutes. The entire substrate is coated with a metallic layer (FIG. 1A, top row, image B). The thickness of the metallic coating is in the range of 0.1-2 microns.
(4) After the metal has been sputter coated, photoresist (both positive tone and negative tone resists have been utilized to achieve the final result) is applied to the diamond using a spin coater with angular velocity ranging from 1000 to 12000 rotations per minute (rpm). The angular velocity is varied according to the anvil geometry in order to apply a uniform resist coating (FIG. 1A, top row, image C).
(5) The resist has been processed according to manufacturer's recommendation by baking it at suitable temperature.
(6) The maskless photolithography instrument is then implemented to expose the substrate in very specific regions with visible light with wavelengths in the 360-450 nm range in a very high resolution pattern (micron scale resolution is achieved) via the digital micro mirror device (DMD) contained as an internal component of the maskless lithographic instrument (FIG. 1A, top row, image D). Depending on the tone of the resist (positive resist becomes soluble when exposed to radiation, whereas negative resist becomes insoluble), the artwork loaded into the lithographic system software is designed specifically to meet the final pattern specifications.
(7) The exposed resist is then placed in a developer solution and a pattern is rendered in the resist layer. The resist that remains is essentially a protective layer for the underlying tungsten film during the next phase of wet etching.
(8) The substrate is immersed in a weakly acidic tungsten etchant. Once the etchant has completely dissolved the excess tungsten in the base layer, the substrate is removed from the solution and the photoresist layer is dissolved in a solvent. The result is a diamond anvil with a metallic pattern drawn on it (FIG. 1A, top row, image E).
(9) The diamond anvil is then transferred into a 1.2 kW MPCVD chamber and single crystal diamond (SCD) is grown at temperatures ranging from 800 to 1300° C. with a CH4/H2 ratio of 1%-10%. This results in the growth of CVD diamond with a thickness of 10-70 microns. The anvil is then polished.

The process of obtaining encapsulated marks on diamond anvils with the use of the lift-off process described further in the following generalized method, with reference to FIG. 1A:
(1) The lift-off process is essentially the reverse process of the wet etch procedure previously described. In the lift-off process the same instrumentation, materials, and process parameters outlined in the wet-etch method are used to perform the fabrication process. However, in this method resist coating and all lithographic process steps occur on the bare SCD substrate prior to sputter deposition (FIG. 1A, bottom row, image A and B).
(2) As a result, once the lithographic process is completed the diamond surface regions in which metal will be deposited to render the final circuit pattern are exposed to incident tungsten atoms (FIG. 1A, bottom row, image C).
(3) During sputter deposition tungsten particles coat these regions and adhere to the diamond substrate surface.
(4) After sputter deposition, the resist layer is stripped from the diamond anvil, and the excess tungsten deposited on top of the resist layer will be removed and only the final circuit pattern remains (FIG. 1A, bottom row, image D).
(5) Resolution enhancement has been achieved by depositing an interstitial under layer of resist prior to applying an imaging resist layer. In this bi-layer method the interstitial layer (base layer of resist deposited directly onto the diamond) has a slightly higher dissolution rate than the imaging resist that is deposited on top of it, this results in an “overhang” effect during the development phase which leads to improved resolution as sputter deposited material is less likely to delaminate from the diamond surface due to attachment of tungsten to the resist coating during the resist stripping phase. Once sputter deposition and resist stripping is complete, the anvil undergoes the same steps as in the encapsulating MPCVD and polishing phase as described above.

5. Methods for Marking a Diamond
a. Preparation and Cleaning of the Diamond Substrate that is to be Inscribed

This step is performed so that the diamond surface is clean and free of contamination, as any debris on the surface can negatively affect the outcome of the sputter deposition and lithographic processes. The cleaning steps are as follows: (a) the diamond crystal is submerged in sulfuric acid which is heated to 60-70° C. for 1 hour; and (b) the diamond is then washed in distilled water, after which it is dried via heating or air blowing.

After the diamond surface is clean and dry, it is typically then processed in one of two ways in order to achieve a final and successful inscription. The processes that the diamond may undergo are known as a lift-off process or a wet etch process. Both processes are outlined separately below.
b. Lift-Off Process

The lift-off process comprises the following steps:
1. The diamond substrate is placed into a spin coater, and is secured into place by way of a vacuum chuck.
2. The diamond is rotated between 2000-8000 rpm for 60 seconds. As rotation is initiated Shipley-1827 positive tone photo-resist is ejected onto the diamond to apply a uniform coating of polymer solution.
3. At the completion of spin coating, the diamond is then baked (known as soft baked) for 5 minutes in a heating oven at 110-120° C.
4. After baking the diamond is removed from the oven and left to sit at ambient conditions for 5 minutes.
5. The diamond is then placed in the SF-100 maskless lithography instrument, in which a very specific portion of the polymer layer is exposed to radiation of wavelength 434 nm.
6. After exposure, the polymer coated diamond is placed in a developer solution, in which all the polymer that was exposed to the 434 nm radiation is dissolved, essentially leaving trenches in the polymer coating in the form of the intended inscription.
7. The polymer coated diamond is then placed in the sputter deposition chamber and is placed under vacuum for 24 hours to achieve an ultrahigh vacuum to make sure that metallic film quality is not degraded by moisture or contaminants in the sputtering chamber.
8. Prior to metallic deposition, the diamond is etched in an 80 Watt RF argon plasma at a pressure of 8 mTorr for two minutes. This cleans the diamond surface that is exposed (in the trenches of the polymer film).
9. After the two minute cleaning etch, the plasma energy is decreased by reducing the RF power source to 4-5 Watts, and the DC-plasma source is initiated which sputters a metallic target (currently tungsten) onto the diamond/polymer surfaces.
10. Metal is uniformly deposited onto both the polymer and into the trenches in the polymer (i.e. onto the exposed diamond surface). After 20-35 minutes of deposition resulting in a metal film thickness of 200-500 nm, the DC power source is turned off, and sputter deposition ceases.
11. The diamond is left to cool in the sputter deposition chamber for 30-60 min to reduce stress induced in the film due to thermal shock, after which it is removed from the sputter chamber.
12. The polymer coating on the diamond is then removed with acetone, which also removes all unwanted tungsten that was deposited onto the polymer surface, leaving behind only the metallic pattern that was deposited directly onto the diamond surface through the open trenches.
c. Wet-Etch Process

The wet etch process is similar to the lift-off process in that it requires metallic deposition, and the same lithographic processing steps as the aforementioned lift-off method. The major differences however, are a changing in the order of these process steps along with the addition of a chemical etching step that is required. The chemical etching step is implemented to dissolve unwanted tungsten from the diamond surface.

Due to the process steps being the same in the wet etch and lift-off techniques, the process steps outlined in the lift-off method will be referenced in the below description of the wet etch process where applicable.

The wet-etch process comprises the following steps:
1. Steps 7-11 eleven are followed. However the diamond substrate is “naked” (has no polymer coating) when it is placed in the sputter deposition chamber. As a result the metallic film is uniformly deposited over the entire diamond surface.
2. Steps 1-6 are implemented with some minor differences. The polymer coating is now coating the tungsten layer that is adhered to the top surface of the diamond. During exposure the exposed portion of the polymer coating is essentially the inverse of that that is exposed in the lift-off process, meaning that the pattern that one wishes to keep on the polymer surface is not exposed to 434 nm radiation. After development there will be a very finely featured pattern of the polymer in the intended design of the inscription remaining on the tungsten surface.
3. Chemical wet etching (metallic etching occurs). The diamond is placed in a weakly acidic chemical etchant solution for a certain amount of time which is dependent on environment variables such as room temperature. The remaining polymer pattern that remains on the tungsten surface acts as a protective mask to the chemical etchant; thereby protecting the underlying tungsten. Any tungsten not protected by the polymer mask is then dissolved in the chemical etchant.
4. The polymer solution is then removed with acetone, and only the intended metallic inscription remains on the diamond surface.
d. Chemical Vapor Deposition

The next process step is Chemical Vapor Deposition (CVD) in which diamond is grown on the surface of the diamond substrate as a lattice continuation. This diamond growth ultimately encapsulates the tungsten pattern and completely covering it in a protective diamond layer. This means that the tungsten pattern is essentially embedded in the diamond, and cannot be removed without significantly damaging the diamond.

The CVD process comprises the following steps:
1. The diamond is placed in a molybdenum substrate holder and is loaded into the CVD chamber.
2. The CVD chamber is placed under vacuum and is pumped down to less than 10 mTorr for 12 hours.
3. When beginning the CVD process, hydrogen is introduced into the chamber and is excited into a plasma through the introduction of a 2.45 GHz microwave source.
4. Chamber pressure is controlled through a vacuum throttle valve, and is gradually increased in conjunction with an increasing of the microwave power source. This causes the chamber temperature to increase in a highly controlled manner, and prevents the metallic film from delaminating (peeling off) due to thermally induced stress.
5. When optimal temperature (between 800-1250° C.) and pressure (at 60-100 mTorr) for diamond growth is reached, nitrogen, oxygen, and methane are also introduced into the CVD chamber and become reactive in the microwave plasma.
6. The diamond substrate undergoes growth for 1-4 hours, until pressure and microwave power are ramped down and the system is shut down.

After the completion of the CVD process, the diamond is polished to remove surface defects, and the procedure is then completed. Rendering a final product that is a diamond with a metallic inscription inside of the diamond, and is protected by all of the impressive mechanical, electrical and thermal properties of a diamond.

It will be apparent to those skilled in the art that various modifications and variations can be made in the present invention without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for preparing an encapsulated marked diamond, the method comprising:
(a) providing a diamond substrate having a surface;
(b) depositing a uniform metal layer onto the surface;
(c) coating the surface with a positive tone photoresist or a negative tone photoresist;
(d) exposing the surface to light, thereby making the positive tone photoresist soluble in developing solution or thereby making the negative tone photoresist insoluble in developing solution;
(e) developing the coating after exposing it to light, thereby creating a pattern onto the coating, thereby exposing any excess metal, and thereby exposing a portion of the surface;
(f) dissolving the excess metal;
(g) stripping the coating; and
(h) encapsulating the surface with single crystal diamond.

2. The method of claim 1, wherein the substrate is a single crystal.

3. The method of claim 1, wherein the metal layer comprises tungsten, gold, silver, palladium, or platinum.

4. The method of claim 1, wherein the metal layer has a thickness of from about 0.1 microns to about 2 microns.

5. The method of claim 1, wherein the coating is a positive tone resist.

6. The method of claim 1, wherein the coating is a negative tone photoresist.

7. The method of claim 1, wherein exposing the surface is via maskless lithography.

8. The method of claim 1, wherein the light that is incident on the surface is in the wavelength range of from about 360 nm to about 450 nm.

9. The method of claim 1, wherein encapsulating is via microwave plasma chemical vapor deposition.

10. The method of claim 1, wherein encapsulating comprises the steps of:
(a) providing a mixture comprising hydrogen and a carbon precursor;
(b) establishing a plasma comprising the mixture; and
(c) depositing carbon-containing species from the plasma onto the surface.

11. An encapsulated marked diamond prepared by the method of claim 1.

12. A method for preparing an encapsulated marked diamond, the method comprising:
(a) providing a diamond substrate having a surface;
(b) applying a photoresist coating onto the surface;
(c) exposing the substrate to light, wherein the light etches a pattern onto the polymer resist coating, thereby exposing a portion of the surface;
(d) depositing a uniform metal layer onto the portion of the surface;
(e) stripping the polymer resist coating; and
(f) encapsulating the surface with single crystal diamond.

13. The method of claim 12, wherein the substrate is a single crystal.

14. The method of claim 12, wherein exposing is via maskless lithography.

15. The method of claim 12, wherein the metal layer comprises tungsten, gold, silver, palladium, or platinum.

16. The method of claim 12, wherein the metal layer is of from about 0.1 microns to about 2 microns.

17. The method of claim 12, wherein encapsulating is via microwave plasma chemical vapor deposition.

18. The method of claim 12, wherein encapsulating comprises the steps of:
(a) providing a mixture comprising hydrogen and a carbon precursor;
(b) establishing a plasma comprising the mixture; and
(c) depositing carbon-containing species from the plasma onto the surface.

19. An encapsulated marked diamond prepared by the method of claim 12.

20. An inscription method comprising:
(a) performing photolithography on a surface of a diamond substrate, thereby producing an image on the surface; and
(b) forming a single crystal diamond on top of the image, thereby encapsulating the image.
